(19) United States
(12) Patent Application Publication
(10) Pub. No.: US 2013/0250380 A1
(43) Pub. Date: Sep. 26, 2013

(54) VIRTUAL IMAGE DISPLAY APPARATUS

(71) Applicant: SEIKO EPSON CORPORATION, Tokyo (JP)

(72) Inventors: Yoichi FUJIKAWA, Azumino-shi (JP); Osamu YOKOYAMA, Shiojiri-shi (JP); Takehiko KUBOTA, Matsumoto-shi (JP)

(73) Assignee: SEIKO EPSON CORPORATION, Tokyo (JP)

(21) Appl. No.: 13/767,383

(22) Filed: Feb. 14, 2013

(30) Foreign Application Priority Data
Mar. 26, 2012 (JP) 2012-069203

(51) Int. Cl. G02B 27/01; H01L 51/52

(52) U.S. Cl. CPC G02B 27/0103; H01L 51/5203
USPC 359/13; 257/40

(57) ABSTRACT

A virtual image display apparatus includes an organic EL device that outputs light having one kind of wavelength band, a light guide member, and a reflection-type volume hologram that is disposed on a first face of the light guide member and diffracts and reflects light of a predetermined wavelength band of the light that has entered. The organic EL device includes an optical resonance structure that causes the above-mentioned light of one-kind wavelength band to resonate.

### INCORPORATION BY REFERENCE

This application claims priority to Japanese Patent Application No. 2012-069203 filed on Mar. 26, 2012, in Japan, which is herein incorporated by reference in its entirety.

### BACKGROUND

1. Technical Field

The present invention relates to virtual image display apparatuses.

2. Related Art

Virtual image display apparatuses are well known that guide image forming light outputted from electro-optical devices, such as a liquid crystal (LC) device, an organic electro luminescence (EL) device and the like, by using virtual image optical systems so as to make the guided light viewed by viewers (for example, see JP-A-2009-300480). Virtual image display apparatuses are used as a head-mounted display (HMD), for example, which is a head-worn type display apparatus and is widely used these days.

The virtual image display apparatus described in JP-A-2009-300480 includes a reflection-type volume hologram that selectively diffracts and reflects light of a specified wavelength band in a virtual image optical system. In this virtual image display apparatus, light outputted from an electro-optical device (image forming unit) is diffracted and reflected by a first reflection-type volume hologram to enter a light guide plate, and the light totally reflected inside the light guide plate is diffracted and reflected by a second reflection-type volume hologram to reach the eye of a viewer.

However, a wavelength range of the light that is diffracted and reflected by a reflection-type volume hologram is narrower with respect to the light having wavelength bands of red, green, blue and so on that is outputted by an electro-optical device. Accordingly, of image forming light outputted by the electro-optical device, light within a diffraction spectrum wavelength range of the reflection-type volume hologram reaches the eye of a viewer, but light outside of the diffraction spectrum wavelength range of the reflection-type volume hologram passes through the reflection-type volume hologram and does not reach the eye of the viewer.

As described above, with a virtual image display apparatus using a reflection-type volume hologram, because only part of the image forming light outputted from an electro-optical device is used for visual recognition by a viewer, an image (virtual image) viewed by the viewer is lower in luminance and visibility in comparison with those of an original image produced in the electro-optical device. For this reason, there has been a problem that the visibility of a virtual image viewed by the viewer is extremely reduced particularly in a case of a virtual image display apparatus such as a see-through type HMD in which an outside scene is transmitted and viewed by the viewer as a background.

### SUMMARY

An advantage of some aspects of the invention is to solve at least part of the above problem, and the invention can be embodied in the following embodiments and application examples.

### Application Example 1

A virtual image display apparatus according to application example 1 includes an organic EL device that outputs light of at least N kinds (N is an integer equal to or greater than 1) of wavelength bands, a light guide member, and a reflection-type volume hologram that is provided on a first face of the light guide member and diffracts and reflects light of a predetermined wavelength band of the light having entered. The organic EL device includes an optical resonance structure that causes light of each of the N kinds of wavelength bands to resonate.

According to this configuration, since the organic EL device included in the virtual image display apparatus has an optical resonance structure that causes light of each of N kinds of wavelength bands to resonate from among the light of at least N kinds of wavelength bands outputted from the organic EL device, this virtual image display apparatus outputs light with a spectrum having a stronger peak intensity and a narrower width in comparison with a case where an organic EL device without the optical resonance structure or a liquid crystal device is used. Accordingly, light intensity of light that enters the reflection-type volume hologram from the organic EL device equipped with the optical resonance structure is stronger in comparison with a case where an organic EL device without the optical resonance structure or a liquid crystal device is used. With this, luminance of the image (virtual image) viewed by the viewer is increased and visibility of the image can be enhanced in the virtual image display apparatus.

### Application Example 2

In the virtual image display apparatus according to the above application example, it is preferable for the light of the N kinds of wavelength bands outputted by the organic EL device to be light that has not passed through a color filter.

According to this configuration, because, of the light outputted by the organic EL device, light other than the light of a predetermined wavelength band to be diffracted and reflected by the reflection-type volume hologram, is not used for displaying a virtual image, light other than the light of the predetermined wavelength band needed for displaying the virtual image, is substantially cut off even if the organic EL device is not equipped with a color filter. With this, since light outputted by the organic EL device can be used without the light passing through a color filter, luminance of the virtual image can be further enhanced. In addition, the organic EL device can be made thinner because color filters are not needed.

### Application Example 3

In the virtual image display apparatus according to the above application examples, it is preferable for the reflection-type volume hologram to include a first reflection-type volume hologram into which light guided inside the light guide member enters, and which diffracts and reflects light of the predetermined wavelength band from among the light having entered and makes the diffracted and reflected light be outputted from the light guide member.

According to this configuration, the first reflection-type volume hologram that diffracts and reflects light of the predetermined wavelength band from among the light guided inside the light guide member, and makes the diffracted and reflected light be outputted toward a viewer, is included in the configuration, thereby making it possible to provide a virtual image display apparatus capable of giving an excellent visibility.

### Application Example 4

In the virtual image display apparatus according to the above application examples, it is preferable for the reflection-type volume hologram to include a second reflection-type volume hologram into which light having been outputted from the organic EL device enters, and which diffracts and reflects light of the predetermined wavelength band from among the light having entered, and guides the diffracted and reflected light inside the light guide member.

According to this configuration, the second reflection-type volume hologram that diffracts and reflects light of a predetermined wavelength band from among the light outputted from the organic EL device so as to guide the diffracted and reflected light inside the light guide member, is included in the configuration, thereby making it possible to provide a virtual image display apparatus capable of giving an excellent visibility.

### Application Example 5

In the virtual image display apparatus according to the above application examples, it is preferable for the light of N kinds of wavelength bands outputted by the organic EL device to include light of a red wavelength band, light of a green wavelength band and light of a blue wavelength band.

According to this configuration, light that is outputted by the organic EL device included in the virtual image display apparatus, includes light of the red wavelength band, light of the green wavelength band and light of the blue wavelength band, and utilization efficiency of light of each of these wavelength bands is enhanced, thereby making it possible for the virtual image display apparatus to display a full-color virtual image with a higher luminance.

### Application Example 6

In the virtual image display apparatus according to the above application examples, it is preferable for the light of the predetermined wavelength band that is diffracted and reflected by the reflection-type volume hologram to correspond to a wavelength band that is caused to resonate in the optical resonance structure.

According to this configuration, because the light of a predetermined wavelength band that is diffracted and reflected by the reflection-type volume hologram corresponds to a wavelength band that is caused to resonate in the optical resonance structure, the amount of light that is diffracted and reflected to reach the eye of a viewer is increased whereas the amount of light that is not diffracted and reflected but passes through is reduced; in other words, utilization efficiency of light in the virtual image display apparatus is enhanced. This makes it possible to further raise the luminance of an image viewed by the viewer and enhance the visibility thereof in the virtual image display apparatus.

### BRIEF DESCRIPTION OF THE DRAWINGS

The invention will be described with reference to the accompanying drawings, wherein like numbers reference like elements.

FIG. 1 is a schematic diagram illustrating a general configuration of a virtual image display apparatus according to a first embodiment of the invention.

FIG. 2 is an equivalent circuit diagram illustrating an electric configuration of an organic EL device according to the first embodiment.

FIG. 3 is a schematic plan view illustrating the configuration of the organic EL device according to the first embodiment.

FIG. 4 is a schematic cross-sectional view illustrating the organic EL device according to the first embodiment.

FIGS. 5A through 5C are diagrams for explaining utilization efficiencies of light given by a reflection-type volume hologram.

FIG. 6 is a schematic cross-sectional view illustrating an organic EL device according to a second embodiment of the invention.

### DESCRIPTION OF EXEMPLARY EMBODIMENTS

Hereinafter, embodiments in which the invention is embodied will be described with reference to the drawings. The drawings used in the following explanation are appropriately enlarged or reduced so that portions of the drawings to be mentioned can be easily recognized. Note that constituent elements other than those needed in the explanation may be omitted in the drawings in some case.

It is to be noted that, in the following descriptions of the embodiments, in the case where, for example, an expression “on a substrate” is given in the description, the expression can have the following meanings; that is, something is “placed in contact with the surface of a substrate”, something is “placed with another something therebetween”, or “a part of something is placed in contact with the surface of a substrate while the other part of it is placed with another something therebetween”.

### First Embodiment

### Virtual Image Display Apparatus

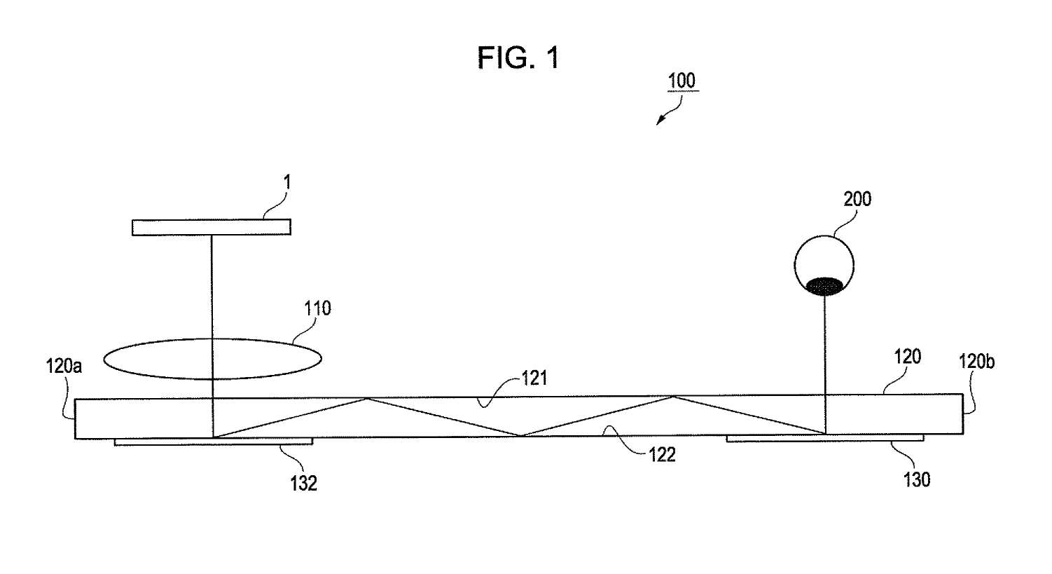

First, a virtual image display apparatus according to a first embodiment of the invention will be described with reference to the drawings. FIG. 1 is a schematic diagram illustrating a general configuration of the virtual image display apparatus according to the first embodiment. The virtual image display apparatus according to the first embodiment is a head-mounted display (HMD) that is worn on the head of a viewer and displays an image (virtual image), and in which an organic EL device as an electro-optical device that outputs image forming light, which is light to form an image, is provided.

As shown in FIG. 1, a virtual image display apparatus 100 includes an organic EL device 1, a collimator 110, a light guide member 120, a reflection-type volume hologram 132 as the first reflection-type volume hologram, and a reflection-type volume hologram 130 as the second reflection-type volume hologram.

The organic EL device 1 outputs light of at least N kinds of wavelength bands (N is an integer equal to or greater than 1). The light of N kinds of wavelength bands includes, for example, light of a red (R) wavelength band, light of a green (G) wavelength band, and light of a blue (B) wavelength band. The organic EL device 1 is capable of forming a full-color image with the light of these R, G and B wavelength bands. Further, the organic EL device 1 is equipped with an optical resonance structure that causes the light of R, G and B wavelength bands to resonate respectively. The configuration of the organic EL device 1 will be described in detail later.

The collimator 110 is interposed between the organic EL device 1 and the light guide member 120. The collimator 110 has a function to convert the light of R, G and B wavelength bands to collimated beams of light. The collimator 110 is configured of a collimator lens or the like. The light of R, G and B wavelength bands, which has been converted to the collimated beams of light by the collimator 110, enters the light guide member 120.

The light guide member 120 has a function that totally reflects the collimated beams of light of R, G and B wavelength bands entering via the collimator 110 and guides them within the guide member. The light guide member 120 is constituted with a material that is formed in a predetermined shape; the material in this case is, for example, a resin having an excellent characteristic of transparency such as an acrylic resin, polycarbonate resin, polystyrene resin or the like, or glass.

The light guide member 120 extends from one end 120a to the other end 120b in a direction that intersects with a direction of the light entering via the collimator 110, and is formed in a thin plate shape, in which a first optical face 121 as a first face arranged on the collimator 110 side and a second optical face 122 opposed to the first optical face 121 are provided as the main faces. In the first optical face 121 of the light guide member 120, a light incidence port through which light enters is provided on the side of the one end 120a, while on the side of the other end 120b, a light output port through which light is outputted is provided.

On the second optical face 122 of the light guide member 120, a reflection-type volume hologram 132 is provided at a position opposed to the light incidence port on the side of the one end 120a, and a reflection-type volume hologram 130 is provided at a position opposed to the light output port on the side of the other end 120b.

In order for the collimated beams of light of R, G and B wavelength bands that enter via the collimator 110 to be totally reflected inside the light guide member 120, the reflection-type volume hologram 132 diffracts and reflects the collimated beams of light of a predetermined wavelength band of each color wavelength band. The reflection-type volume hologram 130 diffracts and reflects the collimated beams of light of a predetermined wavelength band of each color wavelength band toward the eye of a viewer 200 from among the light of R, G and B wavelength bands having been totally reflected and guided inside the light wave guide member 120. With this, an image (virtual image) formed by the image forming light outputted from the organic EL device 1 can be viewed by the viewer.

The reflection-type volume holograms 130 and 132 have a diffraction structure including interference fringes corresponding to each of the N kinds of wavelength bands. The reflection-type volume holograms 130 and 132 according to this embodiment have a diffraction structure corresponding to each of the R, G and B wavelength bands that is made to resonate in the optical resonance structure of the organic EL device 1, and selectively diffract and reflect the light of R, G and B wavelength bands. Note that the half width of the light that is diffracted and reflected by the reflection-type volume holograms 130, 132 is smaller than that of the light that is outputted from the organic EL device 1; details of this will be given later.

As the reflection-type volume holograms 130 and 132, a known structure can be used. The reflection-type volume holograms 130, 132 may have a structure in which interference fringes corresponding to each of the R, G and B wavelength bands are laminated in three layers, or may have a structure in which interference fringes corresponding to each of the R, G and B wavelength bands are formed being overlapped with each other in the same layer.

### Organic EL Device

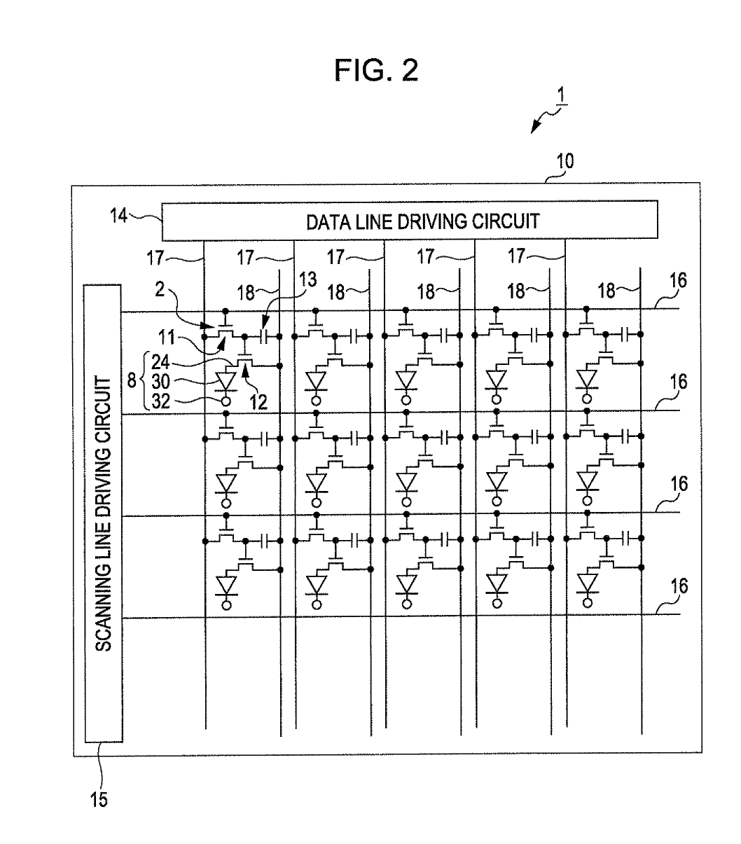

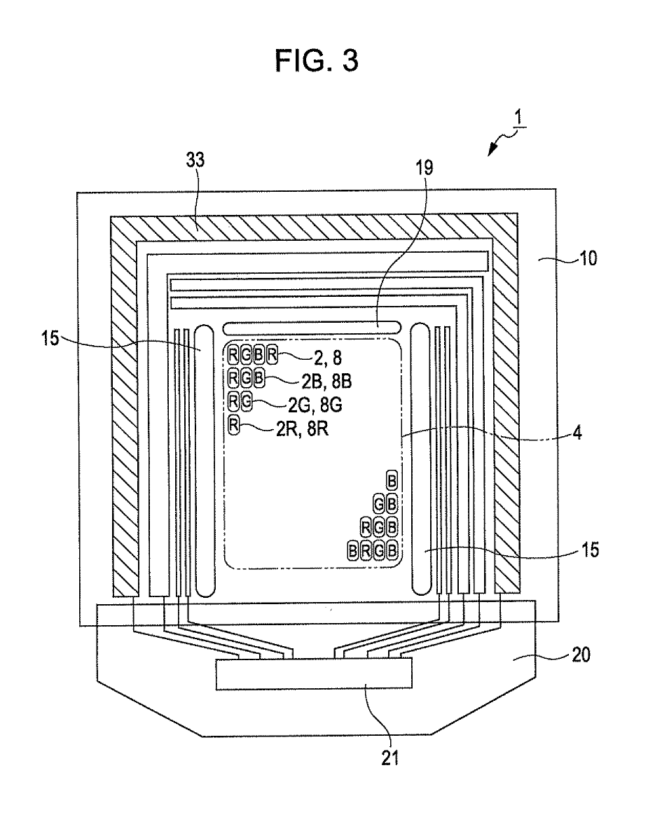

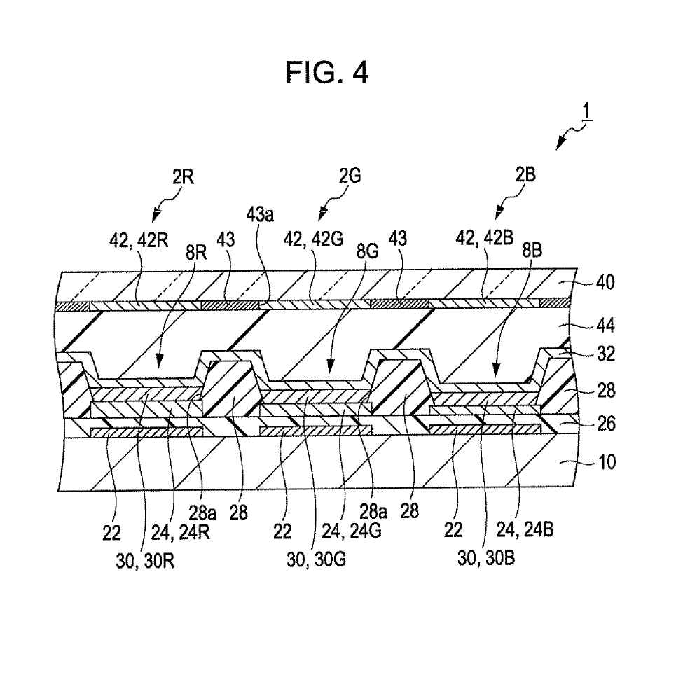

Next, a configuration of the organic EL device according to the first embodiment will be described with reference to the drawings. FIG. 2 is an equivalent circuit diagram illustrating an electric configuration of the organic EL device according to the first embodiment. FIG. 3 is a schematic plan view illustrating the configuration of the organic EL device according to the first embodiment. FIG. 4 is a schematic cross-sectional view illustrating the organic EL device according to the first embodiment.

As shown in FIG. 2, an organic EL device 1 is an active-matrix type organic EL device using thin film transistors (hereinafter, called TFTs) as switching elements. The organic EL device 1 includes a substrate 10, scanning lines 16 disposed on the substrate 10, signal lines 17 extending in a direction that intersects with the scanning lines 16, and power lines 18 extending in parallel to the signal lines 17.

A data line driving circuit 14 having a shift register, a level shifter, a video line, and an analog switch is connected with the signal lines 17. Meanwhile, with the scanning lines 16, a scanning line driving circuit 15 having a shift register and a level shifter is connected.

Regions of sub-pixels 2 are defined by the scanning lines 16 and the signal lines 17. The sub-pixels 2 are a minimum display unit of the organic EL device 1, and arranged in matrix form along an extension direction of the scanning lines 16 and an extension direction of the signal lines 17, for example. Each of the sub-pixels 2 includes a switching TFT 11, a driving TFT12, a retention capacitor 13, an anode 24, a cathode 32 and an organic function layer 30.

The organic function layer 30 is configured of a hole transport layer, a light emitting layer and an electron transport layer, which are laminated in series, for example. The anode 24, the cathode 32 and the organic function layer 30 constitute an organic electro luminescence element (organic EL element) 8. The organic EL element 8 emits light through recombining holes injected from the hole transport layer and electrons injected from the electron transport layer in the light emitting layer.

In the organic EL device 1, when the scanning line 16 is driven and the switching TFT 11 is turned on, an image signal supplied through the signal line 17 is retained by the retention capacitor 13, and a conductive state between the source and the drain of the driving TFT 12 is determined in accordance with the state of the retention capacitor 13. Upon being electrically connected with the power line 18 through the driving TFT 12, a driving electric current flows from the power line 18 to the anode 24, and further flows to the cathode 32 through the organic function layer 30.

The amount of the driving electric current depends upon the conductive state of the source and the drain of the driving TFT12. The light emitting layer of the organic function layer 30 emits light with luminance in proportion to the amount of the electric current that flows between the anode 24 and the cathode 32. In other words, in the case where a light emitting state of the organic EL element 8 is controlled by the driving TFT 12, one of the source and the drain of the driving TFT 12 is electrically connected with the power line 18, and the other one of the source and the drain of the driving TFT 12 is electrically connected with the organic EL element 8.

As shown in FIG. 3, the organic EL device 1 has a light emitting area 4 formed in an approximately rectangular planar shape on the substrate 10. The light emitting area 4 is an area that substantially contributes to the light emission in the organic EL device 1. The organic EL device 1 may have a dummy area that does not substantially contribute to the light emission in the periphery of the light emitting area 4. The sub-pixels 2 are arranged in matrix form in the light emitting area 4. The sub-pixel 2 has an approximately rectangular planar shape, for example. The four corners of the rectangle-shaped sub-pixel 2 may be formed in a round shape.

The organic EL device 1 according to this embodiment includes sub-pixels 2R that output light of a red (R) wavelength band, sub-pixels 2G that output light of a green (G) wavelength band, and sub-pixels 2B that output light of a blue (B) wavelength band (hereinafter, also referred to simply as “sub-pixels 2” if corresponding colors are not needed to be distinguished). Organic EL elements 8R, 8G and 8B are provided corresponding to the sub-pixels 2R, 2G and 2B, respectively (hereinafter, also referred to simply as “organic EL elements 8”, like in the sub-pixels 2, if corresponding colors are not needed to be distinguished).

In the periphery of the light emitting area 4, the two scanning line driving circuits 15 and an inspection circuit 19 are disposed. The inspection circuit 19 is a circuit to inspect an operational status of the organic EL device 1. Cathode wiring 33 is disposed on the circumference of the substrate 10. Further, a flexible substrate 20 is provided at one side of the substrate 10. The flexible substrate 20 includes a driving IC 21 connected with each wiring.

In the organic EL device 1 according to this embodiment, a basic unit in forming an image is configured of a group of the sub-pixels 2R, 2G and 2B; by appropriately changing the luminance of each of the sub-pixels 2R, 2G and 2B at each basic unit, various kinds of colors of light can be outputted. Through this, the organic EL device 1 can display a full-color image or emit full-color light.

As shown in FIG. 4, the organic EL device 1 includes a reflection layer 22, a protection layer 26, the anodes 24, partition walls 28, the organic function layers 30, the cathode 32, a sealing layer 44, and a color filter substrate 40 on the substrate 10. The organic EL device 1 is a top-emission type device in which the light emitted from the organic function layer 30 is outputted to the side of the color filter substrate 40.

It is to be noted that, in this specification, the side of the color filter substrate 40 of the organic EL device 1 in FIG. 4 is called an “upper side”. Further, in this specification, it is called “to view from above” to view the drawing from the direction of a normal line to the surface on the color filter substrate 40 side of the organic EL device 1.

Since the organic EL device 1 is a top-emission type, the substrate 10 may employ any of a transparent material and a nontransparent material for its base material. As the transparent material, glass, quartz, resin (plastic, plastic film) and the like can be cited, for example. As the nontransparent material, ceramics such as alumina, material made by performing insulating processing such as surface oxidation on a metal sheet of such as stainless steel, a thermosetting resin, a thermoplastic resin, films of these resins (plastic films) and the like can be cited.

Although omitted in FIG. 4, the driving TFT 12 (see FIG. 2) including a semiconductor film, a gate insulating layer, a gate electrode, a drain electrode and a source electrode is provided for each sun-pixel 2 (2R, 2G or 2B) on the substrate 10. The substrate 10 may be covered with an insulating layer, a planarizing layer or the like made of silicon dioxide (SiO₂) or the like, for example.

The reflection layer 22 is provided on the substrate 10. The reflection layer 22 is formed with a light reflective material such as aluminum, silver, or alloy whose major elements are aluminum, silver and the like, for example.

The protection layer 26 is provided so as to cover the substrate 10 and the reflection layer 22. The upper surface of the protection layer 26 is planarized. The protection layer 26 is formed with, for example, an inorganic insulating film such as silicon dioxide (SiO₂), silicon nitride (SiN), nitric oxide silicon (SiON) or the like. The protection layer 26 may be formed with organic resin such as an acrylic resin, a polyimide resin or the like.

The anodes 24 (24R, 24G, 24B) are provided on the protection layer 26. The anodes 24R, 24G and 24 are disposed so as to correspond to the sub-pixels 2R, 2G and 2B, respectively. Layer thicknesses of the anodes 24R, 24G and 24 are different from each other in order to adjust an optical distance (light path length) of the optical resonance structure to be explained later, and are set thicker in the order from the anode 24B, anode 24G and to anode 24R. The anode 24 is formed with transparent conductive material such as indium tin oxide (ITO), ZnO₂ or the like, for example.

The partition walls 28 are provided on the protection layer 26. The partition wall 28 has an opening 28a to define a region of the sub-pixel 2. The opening 28a is formed one size smaller than the anode 24 when viewed from above. The partition wall 28 is formed along the periphery of the opening 28a and overlies the peripheral border of the anode 24 by a predetermined width. The partition wall 28 is formed with an acrylic resin or the like.

The organic function layers 30 (30R, 30G, 30B) are formed on the anodes 24 and arranged within the opening 28a of the partition wall 28. The organic EL device 1 according to this embodiment includes an organic function layer 30R that emits light of the red (R) wavelength band, an organic function 30G that emits light of the green (G) wavelength band, and an organic function layer 30B that emits light of the blue (B) wavelength band as the organic function layers 30. In other words, the organic function layers 30R, 30G, and 30B are formed by applying materials thereto that respectively emit light of R, G and B colors, corresponding to the sub-pixels 2R, 2G and 2B.

The organic function layers 30R, 30G and 30B are each configured of, for example, a hole transport layer, a light emitting layer and an electron transport layer. In the organic function layers 30R, 30G and 30B, light of different wavelength bands of R, G and B can be obtained by recombining holes injected from the hole transport layer and electrons injected from the electron transport layer in the light emitting layer. These layers constituting the organic function layers 30R, 30G and 30B can be formed using known materials.

The cathode 32 is provided so as to cover the partition walls 28 and the organic function layers 30. The cathode 32 is continuously formed across the plural sub-pixels 2 (organic EL elements 8). The cathode 32 functions as a semi-transmissive reflection layer having a property that transmits a part of light that has reached the surface thereof and reflects the other part of the light (that is, semi-transmissive reflectivity). The cathode 32 is formed with magnesium (Mg), silver (Ag), or an alloy the major elements of which are these metals, or the like.

The anodes 24 (24R, 24G, 24B), the organic function layers 30 (30R, 30G, 30B) and the cathode 32 configure the organic EL elements 8 (8R, 8G, 8B). The organic EL elements 8R, 8G and 8B are disposed corresponding to the sub-pixels 2R, 2G and 2B.

Although not illustrated, a passivation layer is provided on the cathode 32. The passivation layer is a protection film to prevent deterioration of the organic EL elements 8 caused by entering oxygen, moisture, or the like. The passivation layer is formed with, for example, an inorganic material with low gas transmittance such as SiO₂, SiN, SiON or the like.

On the substrate 10 where the plurality of organic EL elements 8 (8R, 8G, 8B) are formed, the color filter substrate 40 is disposed opposing to the substrate 10. The color filter substrate 40 is configured with a transparent material such as glass. The color filters 42 (42R, 42G, 42B) and a light blocking layer 43 are formed on a surface of the substrate 10 side of the color filter substrate 40.

The organic EL device 1 includes, as the color filters 42, a color filter 42R corresponding to the red (R) wavelength band, a color filter 42G corresponding to the green (G) wavelength band and a color filter 42B corresponding to the blue (B) wavelength band. The color filters 42R, 42G and 42B are respectively disposed corresponding to the sub-pixels 2R, 2G and 2B, and arranged so as to overlap with the organic EL elements 8R, 8G and 8B when viewed from above. The color filters 42R, 42G and 42B selectively pass light of R, G and B wavelength bands from among the light outputted from the organic EL elements 8R, 8G and 8B.

The light blocking layer 43 includes openings 43a corresponding to the organic EL elements 8R, 8G and 8B, and defines the color filters 42R, 42G and 42B by the openings 43a.

The color filter substrate 40 in which the color filters 42R, 42G, 42B and the light blocking layer 43 are formed is bonded to the substrate 10 via the sealing layer 44. The sealing layer 44 is formed with a transparent resin, for example, a cured resin such as an epoxy resin or the like.

### Optical Resonance Structure

Next, an optical resonance structure included in the organic EL device 1 according to this embodiment will be described. Optical resonators that cause the light emitted in the organic function layers 30 (30R, 30G, 30B) to resonate, are formed between the reflection layer 22 and the cathode 32.

At least part of light emitted in the organic function layers 30 (30R, 30G, 30B) resonates guided by the optical resonator, and light of a resonant wavelength corresponding to an optical distance (light path length) of the optical resonator is enhanced. The resonance guided by the optical resonator is carried out while the light travelling back and forth between the reflection layer 22 and the cathode 32. The light that has resonated in the resonator passes through the cathode 32 so as to be outputted to the upper side. Accordingly, it is possible to enhance the luminance of the light of R, G and B wavelength bands outputted from the organic EL device 1 and obtain the light having a narrower half width.

The resonant wavelength in the optical resonator can be adjusted by changing the optical distance between the reflection layer 22 and the cathode 32. When an optical distance between the reflection layer 22 and the cathode 32 is referred to as “L”, and “λ,” is a peak wavelength of the spectrum of the light which is needed to be taken out from among the light emitted in the organic function layer 30, the following relational expression holds. Note that (I) (radian) is a phase shift which takes place when light emitted in the organic function layer 30 reflects off at both ends of the optical resonator (for example, at the reflection layer 22 and the cathode 32).

(2L)/λ+Φ/(2π)=m (m is an integer)

In the organic EL device 1, in order for the resonant wavelength of each of the optical resonators to become the predetermined value λ corresponding to each of the light of R, G and B wavelength bands outputted by the sub-pixels 2R, 2G and 2B, the optical distance L of the optical resonator is optimized by appropriately setting the layer thicknesses of the anodes 24R, 24G and 24B.

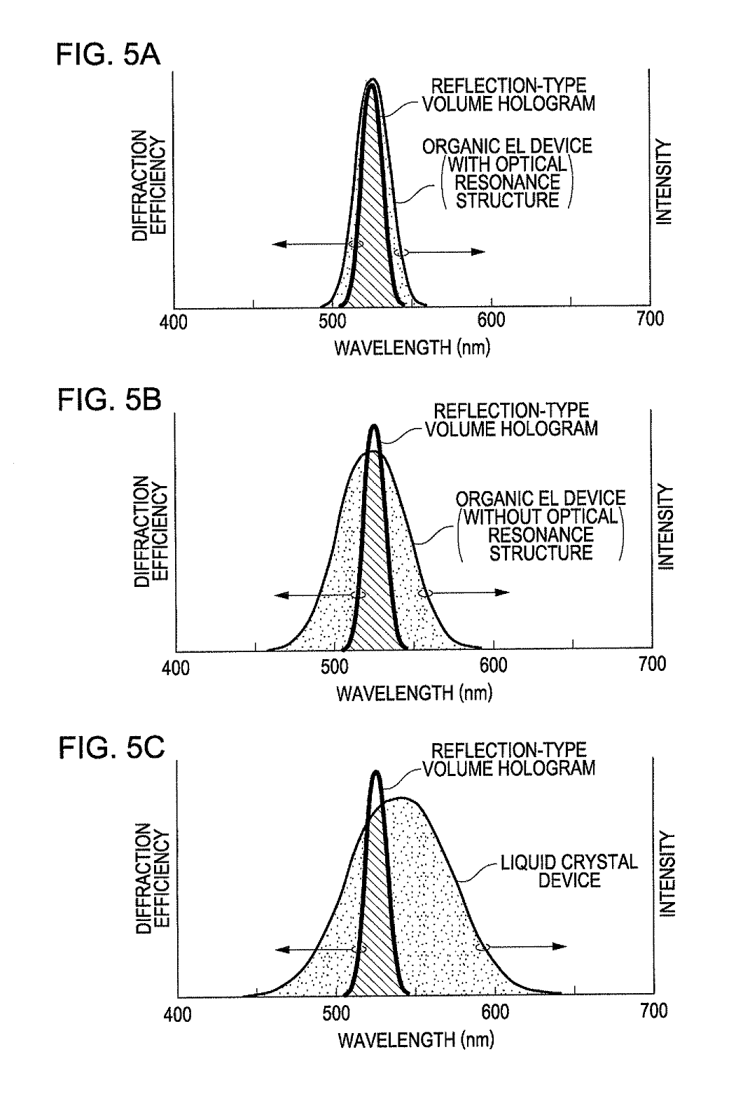

Next, utilization efficiency of light given by the reflection-type volume holograms 130 and 132 of the virtual image display apparatus will be described with reference to the drawings. FIGS. 5A through 5C are diagrams for explaining utilization efficiencies of light given by the reflection-type volume hologram.

Specifically, FIGS. 5A through 5C compare and indicate utilization efficiencies of light given by the reflection-type volume hologram with regard to the light of the green (G) wavelength band, in which the configuration of each electro-optical device that outputs an image forming light is changed. FIG. 5A indicates a case in which an organic EL device including an optical resonance structure, like in the organic EL device 1 of this embodiment, is used as the electro-optical device. FIG. 5B indicates a case in which an organic EL device without an optical resonance structure is used as the electro-optical device. FIG. 5C indicates a case in which a liquid crystal device is used as the electro-optical device.

In each of FIGS. 5A through 5C, the horizontal axis represents a wavelength (unit: nm); while the vertical axis represents diffraction efficiency of the reflection-type volume hologram and also represents spectrum intensity of the organic EL device or the liquid crystal device. Note that the same reflection-type volume hologram is used in FIGS. 5A through 5C.

The reflection-type volume hologram, as described earlier, has a diffraction structure including an interference fringe corresponding to a predetermined wavelength band, and selectively diffracts and reflects light of the predetermined wavelength band while passing therethrough light other than the light of the predetermined wavelength band. Note that a diffraction spectrum of the reflection-type volume hologram is narrow in width, and in the examples of FIGS. 5A through 5C, the half width thereof is around 15 nm, for example. In the virtual image display apparatus, light that is diffracted and reflected by the reflection-type volume hologram reaches the eye of a viewer, whereas light that passes through the reflection-type volume hologram does not reach the eye of the viewer and not used.

First, the case of using a liquid crystal device illustrated in FIG. 5C is described. In the liquid crystal device, light outputted from a light source is modulated in a liquid crystal layer, then light of a specified wavelength band (green in this case) having passed through a color filter is outputted. As shown in FIG. 5C, the half width of light outputted from the liquid crystal device is wider, and is around five times the half width of a diffraction spectrum of the reflection-type volume hologram. Of the light outputted from this liquid crystal device, light that falls in a diffraction spectrum range of the reflection-type volume hologram (indicated by diagonal lines in FIG. 5C) is diffracted, reflected and used by the reflection-type volume hologram. Meanwhile, of the light outputted from the crystal liquid device, light outside of the diffraction spectrum range of the reflection-type volume hologram (indicated by dots in FIG. 5C) passes through the reflection-type volume hologram and is not used.

As described above, in the case where a liquid crystal device is used in the virtual image display apparatus, of the light outputted by the liquid crystal device, light that reaches the eye of a viewer is small in quantity, and light that does not reach the eye of the viewer is extremely large in quantity. Accordingly, the luminance of an image (virtual image) viewed by the viewer is lower in comparison with an original image produced in the liquid crystal device, and in turn the visibility thereof is extremely lowered. Therefore, in order to ensure an appropriate luminance of a virtual image which is viewed by the viewer, electric power to drive the light source of the liquid crystal device is needed to be larger.

As shown in FIG. 5B, the half width of light outputted from the organic EL device without an optical resonance structure is narrower than that of the liquid crystal device, and is around three times the half width of the diffraction spectrum of the reflection-type volume hologram. Accordingly, with the organic EL device, because an amount of light that passes through the reflection-type volume hologram and is not used becomes less (indicated by dots in FIG. 53) in comparison with the case of using the liquid crystal device, the utilization efficiency of light can be improved.

As shown in FIG. 5A, the half width of light outputted from the organic EL device having an optical resonance structure is narrower than that of the organic EL device without an optical resonance structure, and has a value close to the half width of the diffraction spectrum of the reflection-type volume hologram. Accordingly, with the organic EL device having an optical resonance structure, an amount of light that passes through the reflection-type volume hologram and is not used becomes further less (indicated by dots in FIG. 5A) in comparison with the case of using the organic EL device without an optical resonance structure, so that the utilization efficiency of light is further improved.

Moreover, the peak of light outputted from the organic EL device having an optical resonance structure is higher than that of the organic EL device without an optical resonance structure. Accordingly, with the organic EL device having an optical resonance structure, the amount of light that is diffracted, reflected, and guided to reach the eye of the viewer by the reflection-type volume hologram is larger (indicated by diagonal lines in FIG. 5A) in comparison with the case of using the organic EL device without an optical resonance structure.

As described thus far, with the virtual image display apparatus 100 according to the first embodiment of the invention, by including the organic EL device 1 having an optical resonance structure, the utilization efficiency of the light that the organic EL device 1 outputs is improved and the light that reaches the eye of a viewer is large in quantity, thereby making it possible to enhance the luminance of a virtual image viewed by the viewer and in turn enhance the visibility thereof. Accordingly, the virtual image display apparatus according to this invention can be appropriately used as a visual image display apparatus like a see-through type HMD in which an outside scene is transmitted and viewed as a background.

### Second Embodiment

Hereinafter, the configuration of a virtual image display system according to a second embodiment of the invention will be described. The virtual image display apparatus of the second embodiment differs from the first embodiment in that the configuration of an organic EL device is different from that of the first embodiment; however, other constituent elements than this one are approximately the same as those of the first embodiment. Therefore, the configuration of the organic EL device according to the second embodiment will be mainly discussed below with reference to the drawings.

### Organic EL Device

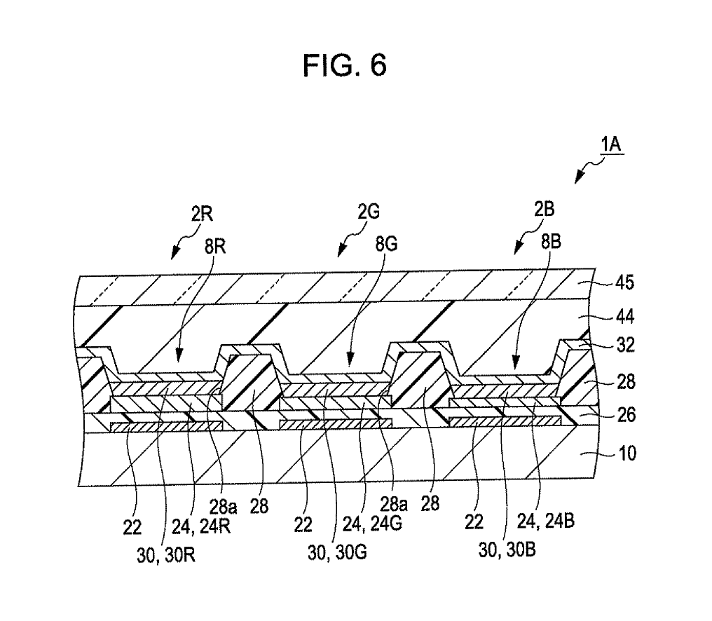

FIG. 6 is a schematic cross-sectional view illustrating the structure of the organic EL device according to the second embodiment. Although an organic EL device 1A according to the second embodiment differs from the organic EL device 1 of the first embodiment in that the organic EL device 1A does not include a color filter, other constituent elements than this one are approximately the same. Note that in the second embodiment, same reference numerals are given to the same constituent elements as those of the first embodiment, and the description thereof will be omitted.

As shown in FIG. 6, the organic EL device 1A includes the reflection layer 22, the protection layer 26, the anodes 24, the partition walls 28, the organic function layers 30, the cathode 32, the sealing layer 44, and a sealing substrate 45 on the substrate 10. In other words, the organic EL device 1A includes, in place of the color filter substrate 40 in the organic EL device 1, the sealing substrate 45 without the color filters 42. Accordingly, the organic EL device 1A outputs the light that has not passed through the color filters 42.

The sealing substrate 45, like the color filter substrate 40, is configured with a transparent material such as glass. The sealing substrate 45 has a function to protect the organic EL elements 8 against an impact shock or the like from outside. Note that it is possible to remove the sealing substrate 45 if the sealing layer 44 can satisfactorily protect the organic EL elements 8.

The organic EL device 1A according to the second embodiment does not have a color filter. However, in the virtual image display apparatus according to the second embodiment, like in the virtual image display apparatus 100 according to the first embodiment, of the image forming light outputted by the organic EL device 1A, light outside of the diffraction spectrum wavelength range of the reflection-type volume holograms 130, 132 (see FIG. 1) is not diffracted and reflected, and is not used in displaying a virtual image. To rephrase, even if the organic EL device 1A does not have a color filter, the reflection-type volume holograms 130, 132 substantially cut off other light than the light within the range of the wavelength band necessary for displaying a virtual image.

Accordingly, with the virtual image display apparatus according to the second embodiment, the following effects can be obtained in addition to the effects obtained in the first embodiment; that is, it is possible to further enhance the luminance of a virtual image viewed by the viewer and further improve the visibility of the virtual image because the image forming light outputted by the organic EL device 1A can be used without the light passing through the color filter. Moreover, since the color filter is not needed, it is possible to make the organic EL device 1A thinner and to lessen the manufacturing man-hour of the organic EL device 1A in comparison with the first embodiment.

It is to be noted that the above embodiments are intended only to explain some aspects of the invention, and any variations and applications can be made arbitrarily within the range and spirit of the invention. As the variations, the following can be cited, for example.

### Variation 1

The virtual image display apparatus 100 according to the above embodiments includes the reflection-type volume hologram 132 at a position opposed to the light incidence port of the light guide member 120, and the reflection-type volume hologram 130 at a position opposed to the light output port; however, the invention is not limited thereto. The virtual image display apparatus may include a light path changing unit such as a reflection mirror in place of the reflection-type volume hologram at either a position opposed to the light incidence port of the light guide member 120 or a position opposed to the light output port. If the virtual image display apparatus includes a reflection-type volume hologram at at least one of a position opposed to the light incidence port of the light guide member 120 and a position opposed to the light output port, it is possible to selectively use the light of a necessary wavelength band for displaying a virtual image.

### Variation 2

In the organic EL devices 1 and 1A of the above embodiments, the organic function layers 30 (30R, 30G, 30B) are each formed by being applied different materials each of which emits light of R, G or B color; however, the invention is not limited thereto. The organic function layers 30 may be formed with a material that emits white light, that is, a material that emits light of equal to or more than four wavelength bands including the R, G and B wavelength bands. To rephrase, the number of wavelength bands in the light emitted by the organic function layers 30 may exceeds the number of resonant wavelengths in the optical resonance structure.

The organic EL device has an optical resonance structure, and the optical distance of the optical resonance structure is optimized so that the resonant wavelength in each of the sub-pixels 2R, 2G and 2B corresponds to each of the light of R, G and B wavelength bands even in a case where the organic function layers 30 have a configuration in which the light of white is emitted. Moreover, in the virtual image display apparatus, because, of the light outputted from the organic EL device, light outside of the ranges of diffraction spectrum wavelengths of the reflection-type volume holograms 130 and 132, is not diffracted and reflected, it is possible to selectively use the light of a necessary wavelength band for displaying a virtual image. In the case where the organic function layers 30 are formed with a material that emits white light, it is possible to form the organic function layers 30 in the same layer across the sub-pixels 2R, 2G and 2B. Further, by forming the organic function layers 30 in the same layer across the sub-pixels 2R, 2G and 2B, because it is not necessary to carry out patterning individually for each of the sub-pixels 2R, 2G and 2B, this technique may be preferably applied in a case such that the sub-pixels 2R, 2G and 2B are less than 20 μm in size.

### Variation 3

In the organic EL devices 1 and 1A of the above-described embodiments, although light of three-kind wavelength bands, i.e., R, G and B wavelength bands, is guided to resonate, light of 1, 2, 4 or more-kind wavelength bands may be guided to resonate. Of the light of plural wavelength bands emitted by the organic function layers 30, it is preferable that light of at least part of the plural wavelength bands be guided to resonate. For example, if there exist three-kind wavelength bands in the light that is emitted by the organic function layers 30, the number of the wavelength bands that are guided to resonate in the resonator may be equal to or less than three. In the case where the organic function layers 30 have a configuration in which white light is emitted, the number of the wavelength bands that are guided to resonate in the resonator may be four, three, two, or just one. On the other hand, the number of the wavelength band guided to resonate in the resonator may be equal to or greater than five.

It is preferable that wavelength bands and peak wavelengths diffracted and reflected by the reflection-type volume hologram 130 or 132 be set so as to correspond to wavelength bands and peak wavelengths guided to resonate in the resonator. For example, if there are three kinds of wavelength bands that resonate in the resonator, it is preferable that three kinds of wavelength bands and peak wavelengths be provided which are diffracted and reflected by the reflection-type volume hologram 130 or 132, corresponding to the wavelength bands and peak wavelengths that resonate in the resonator. Through this, light enhanced by the resonator can be efficiently diffracted and reflected by the reflection-type volume hologram 130 or 132. Note that the wavelength bands and peak wavelengths diffracted and reflected by the reflection-type volume hologram 130 or 132, are not needed to be completely the same as the wavelength bands and peak wavelengths guided to resonate in the resonator; that is, the wavelength bands diffracted and reflected by the reflection-type volume hologram 130 or 132 may be narrower in width, and/or the peak wavelengths may be deviated due to some manufacturing conditions or the like. The wavelength bands and the peak wavelengths diffracted and reflected by the reflection-type volume hologram 130 or 132 and the wavelength bands and the peak wavelengths guided to resonate in the resonator may be set so as to enhance the utilization efficiency of light.

### Variation 4

The organic EL devices 1 and 1A of the above-described embodiments have a configuration in which light of three-kind wavelength bands, i.e., light of R, G and B wavelength bands is emitted; however, the invention is not limited thereto. The organic EL devices 1 and 1A may have a configuration in which, as the light of N-kind wavelength bands, light of one, two, four or more kinds of wavelength bands is emitted.

### Variation 5

In the organic EL devices 1 and 1A of the above-described embodiments, the optical distance of the optical resonator is optimized by changing each of the layer thicknesses of the anodes 24 corresponding to the sub-pixels 2R, 2G and 2B; however, the invention is not limited thereto. The optical distance of the optical resonator may be optimized by changing the layer thickness of the insulating layer interposed between the reflection layer 22 and the cathode 32, corresponding to the sub-pixels 2R, 2G and 2B, or by laminating a plurality of insulating layers or conductive layers.

### Variation 6

In the organic EL devices 1 and 1A of the above-described embodiments, although glass, quartz, resin (plastic, plastic film), ceramics and the like are cited as a material of the substrate 10, a semiconductor substrate such as silicon may also be cited. In this case, transistors that configure the switching TFT 11, the driving TFT 12, the data line driving circuit 14, the scanning line driving circuit 15 and the like are not needed to be a thin film transistor including a semiconductor thin-film layer, and may be a transistor with a channel being formed in the semiconductor substrate itself. In addition, the substrate 10 may be configured with an SOI substrate.

What is claimed is:

1. A virtual image display apparatus comprising:
an organic EL device that outputs light of at least one kind of wavelength band;
a light guide member; and
a reflection-type volume hologram element that is provided on a first face of the light guide member; and
diffracts and reflects light of a predetermined wavelength band of the light that has entered,
the organic EL device including an optical resonance structure that causes light of the at least one kind of wavelength band to resonate.

2. The virtual image display apparatus according to claim 1, further comprising:
the light of the at least one kind of wavelength band outputted by the organic EL device being light that has not passed through a color filter.

3. The virtual image display apparatus according to claim 1, further comprising:
the reflection-type volume hologram element including a first reflection-type volume hologram element into which light guided inside the light guide member enters, and
which diffracts and reflects light of the predetermined wavelength band from among the light having entered and makes the diffracted and reflected light be outputted from the light guide member.

4. The virtual image display apparatus according to claim 1, further comprising:
the reflection-type volume hologram element including a second reflection-type volume hologram element into which light having been outputted from the organic EL device enters, and
which diffracts and reflects light of the predetermined wavelength band from among the light having entered, and guides the diffracted and reflected light inside the light guide member.

5. The virtual image display apparatus according to claim 1, further comprising:
the light of the at least one kind of wavelength band outputted by the organic EL device including light of a red wavelength band, light of a green wavelength band and light of a blue wavelength band.

6. The virtual image display apparatus according to claim 1, further comprising:
the light of the predetermined wavelength band that is diffracted and reflected by the reflection-type volume hologram element corresponding to a wavelength band that is caused to resonate in the optical resonance structure.

7. A virtual image display apparatus comprising:
an organic EL device that outputs light at least having a first wavelength band;
a light guide member; and
a reflection-type volume hologram element that is disposed on a first face of the light guide member, and diffracts and reflects light of a predetermined wavelength band from among the light that has entered,
the organic EL device including an optical resonance structure that causes the light of the first wavelength band to resonate.

8. An organic EL device to be used in a virtual image display apparatus, the organic EL device comprising:
a substrate;
a reflection layer formed on the substrate;
a cathode formed opposing the reflection layer;
at least one anode among a plurality of anodes provided on the reflection layer;
a layer thickness of the at least one anode among a plurality of anodes being different than a layer thickness of another anode among the plurality of anodes, such that an optical distance between the reflection layer and the cathode is varied; and
an optical resonance structure being formed between the reflection layer and the cathode;
a resonant wavelength in the optical resonator being varied by changing the optical distance between the reflection layer and the cathode.

9. The virtual image display apparatus according to claim 1, further comprising:
the organic EL device further including:
a substrate;
a reflection layer formed on the substrate;
a cathode formed opposing the reflection layer;
at least one anode among a plurality of anodes provided on the reflection layer;
a layer thickness of the at least one anode among a plurality of anodes being different than a layer thickness of another anode among the plurality of anodes, such that an optical distance between the reflection layer and the cathode is varied; and
the optical resonance structure being formed between the reflection layer and the cathode;
a resonant wavelength in the optical resonance structure being varied by changing the optical distance between the reflection layer and the cathode.
